(19) United States
(12) Patent Application Publication
(10) Pub. No.: US 2011/0253211 A1
(43) Pub. Date: Oct. 20, 2011

(54) SOLAR CELL AND METHOD FOR MANUFACTURING SAME

(75) Inventor: Hans-Joachim Krokoszinski, Nussloch (DE)

(73) Assignee: ROBERT BOSCH GMBH, Stuttgart (DE)

(21) Appl. No.: 12/998,541

(22) PCT Filed: Oct. 13, 2009
(86) PCT No.: PCT/EP2009/063341

§ 371 Date: Jun. 30, 2011

(30) Foreign Application Priority Data
Oct. 31, 2008 (DE) 10 2008 054 167.2
Jun. 30, 2009 (DE) 10 2009 031 151.3

(51) Int. Cl. H01L 31/0224; H01L 31/18

(52) U.S. Cl. 136/256; 438/98; 257/E31.124

(57) ABSTRACT

A solar cell an n-doped silicon substrate, having n⁺ base regions provided in the first main surface and a p⁺ doped emitter region provided in the second main surface, a finger-like base contact structure applied to the first main surface, an emitter contact and base contact paths applied to the second main surface, each having solderable contact surfaces as well as through-connections (vias) which connect the finger-like contact structure of the first main surface to the base contact paths on the second main surface, thus connecting the emitter region as well as the base regions via the solder contact surfaces on the second main surface. The second main surface is free from p⁺ emitter doping in places, and the first main surface and predetermined regions of the second main surface have an n⁺n transition.

### BACKGROUND OF THE INVENTION

1. Field of the Invention

The present invention relates to a solar cell having an n-doped semiconductor substrate, in particular made of silicon, having base regions on the front side, a finger-like base contact structure applied to the front side, base contact paths on the back side, and through-connections (vias) which connect the finger-like contact structure to the contact paths, and a method for manufacturing same.

2. Description of Related Art

Solar cells having contact fingers on the front side which are connected via laser-bored, metal-filled holes to solderable contact paths (busbars) on the back side have been known for quite some time (Patent Abstracts of Japan, Publication No. 58-039071 (1983); Patent Abstracts of Japan, Publication No. 04223378 (1992)). These solar cells, referred to as metal wrap through (MWT) cells, are provided on p-doped base material which is usually multicrystalline, and which has an emitter that is produced on the front side by phosphorus diffusion (F. Clement et al., 23rd EUPVSEC, Valencia (2008), paper 2DV.1.10). The same as in standard solar cells, the back side is covered with aluminum paste over a large surface between the back side emitter busbars and the base contact solder points in order to form a so-called back surface field (BSF) and to apply metal plating to the back side.

For example, published European patent document EP 0985233 B1 or published international patent application document WO/1998/054763 describes an MWT cell as well as n- and p-doped wafers as starting material, having a homogeneous emitter on the front side, in the through-connections, and in regions of the back side around the through-connections. The areas where the base contacts are to be subsequently situated on the back side are covered by a masking layer during the POCl₃ diffusion of the emitter, the masking layer being subsequently removed before the back side metal plating is applied.

In addition to passivation of the emitter, passivated rear side BSF having local contacts for so-called passivated emitter and rear (local) contacts (PERC) cells have also been proposed in the past (A. W. Blakers et al., Appl. Phys. Lett., 55 (1989), pp.1363-1365; G. Agostinelli et al., 20th European Photovoltaic Solar Energy Conference (2005), Barcelona, p. 647, P. Choulat et al., 22nd European Photovoltaic Solar Energy Conference (2007), Milan).

The following disadvantages of known MWT cells have been identified:

Standard MWT cells have the emitter on the front side, and for a connection to the emitter busbars on the back side must have closed emitter doping at the walls of the holes, which are usually laser-bored holes, to prevent shunting to the base material. Therefore, the holes must be perfectly lined with the aid of diffusion from the gas phase, using POCl₃ (for p material) or BBr₃ (for n material), for example.

In addition, this makes it difficult to also insulate the emitter doping in a strip in the region of the provided back-side emitter busbars with respect to the adjacent back-side doping (BSF). Heretofore, as mentioned above, the back-side BSF has been provided by Al screen printing and sintering, i.e., by overcompensating for the phosphorus doping previously introduced into both surfaces. Although the back-side emitter strips are left exposed during the printing, the insulation between the p⁺ regions and n⁺ regions must be subsequently provided, for example by a laser groove around the emitter busbars.

### BRIEF SUMMARY OF THE INVENTION

An object of the present invention is to provide an improved solar cell which is contacted completely from the back side, and which may be reliably manufactured with high yield and which offers flexible options with regard to specific contacting and passivation, as well as a corresponding manufacturing method.

A novel solar cell structure and a process step sequence (as an example) for manufacturing a corresponding solar cell are proposed, the solar cell containing a full-surface aluminum emitter on the back side of the n-silicon wafer, and FSF contact fingers on the front side which via laser boreholes are connected to solder contact paths or solder contact path segments on the back side, and which are situated in recesses in the otherwise full-surface emitter and in the otherwise full-surface aluminum plating or the otherwise full-surface dielectric passivation layer having local through-connections in the otherwise full-surface aluminum plating.

In advantageous embodiments, the proposed novel MWT cell concept provides that

a) the starting material is preferably, but not necessarily, a monocrystalline n-silicon wafer having any desired shape;

b) in contrast to all concepts according to the related art, the emitter is situated on the back side of an n-type wafer; i.e., the front side and the hole inner walls have an n⁺n transition instead of a pn transition;

c) the p⁺ emitter doping is provided by Al diffusion from a thin swelling layer or swelling layer sequence produced by vapor deposition or sputtering;

d) an Al-based thin-layer metal plating of the emitter on the back side is optionally applied directly over the entire surface, or with the aid of passivation with local contacting of the emitter (PERC);

e) solderable (Ag) contact surfaces may be applied on the Al-based thin-layer metal plating of the (passivated or unpassivated) emitter and in the regions of the BSF left exposed in the emitter;

f) the insulation between the back-side emitter and the BSF doping regions passing through the vias on the back side has already been provided during the production process, so that subsequent laser groove insulation is no longer necessary.

The proposed MWT solar cell structure in its preferred embodiments, in particular having an aluminum-diffused p⁺ emitter on the back side of an n-doped wafer, which on the front side has a standard silver finger H grid on a phosphorus-based n⁺ doping having silicon nitride passivation or an antireflection coating (ARC), the H grid in turn being connected on the back side, via laser-bored holes (vias) filled with silver paste, to busbars which may also be composed of numerous busbar dots situated linearly one behind the other, has the following advantages:

1) n-base-doped wafers have a longer lifetime of the minority charge carriers (in the present case: holes), and therefore allow an MWT cell design having back-side emitters for the present customary wafer thicknesses of 180 μm±20 μm.

2) Since the walls of the vias, the same as the front side, have only one n⁺n high-low transition (unlike the standard MWT cell on p wafers having a front-side n⁺ emitter and n⁺ emitter doping in the vias), there is no risk of shunting and j₀₂ increase in the vias; the reason is that if the hole metal plating is to contact through the highly doped n⁺ layer, the contact still remains in the base polarity region (n).

3) Pastes 1 and 2 may be the same due to the fact that the back-side base contact surface regions, the holes, and the front side are n⁺-doped, and the silver pastes may contact without risk through the ARC, and on the back side, through the n⁺ layer (see item 2), even without the ARC.

4) Due to the fact that the back-side passivation layer is deposited only after firing of the front-side silver fingers, the back-side base contact surfaces, and the hole metal plating, the back-side passivation layer does not have to withstand high-temperature treatments at T>800° C.; the highest temperature that this layer must subsequently withstand is the low sintering temperature of back-side emitter contact surface paste 3 (<560° C.), resulting in better chances of successful back-side passivation.

5) Due to the fact that the aluminum emitter doping is structured in such a way that the back-side FSF busbar regions may be produced in narrower strips or dots than those which have been previously left exposed in the emitter, no laser groove-based insulation of the p⁺ and n⁺ areas is necessary at the conclusion of the cell manufacturing process.

### BRIEF DESCRIPTION OF THE DRAWINGS

FIGS. 1 through 21 illustrate the various method steps of manufacturing an example embodiment of the solar cell according to the present invention.

### DETAILED DESCRIPTION OF THE INVENTION

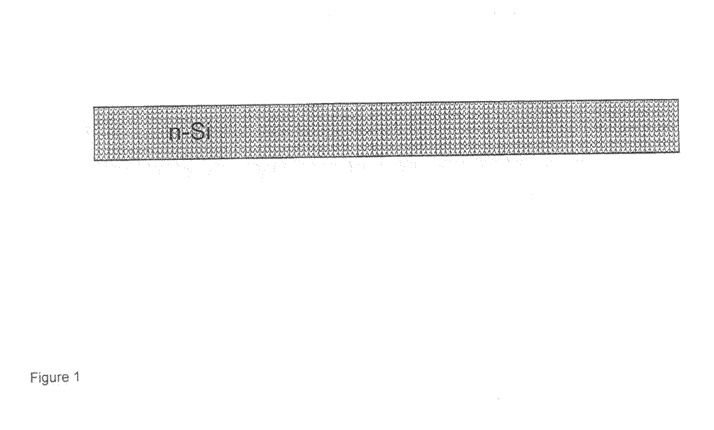

FIGS. 1 through 21 show schematic detail illustrations of one example embodiment of the solar cell and the manufacturing method according to the present invention, in cross sections or bottom views (top views of the second main surface). Due to the illustrated coating sequence, the individual figures for the most part are self-explanatory; therefore, the following description is provided merely in outline form and is understood to be a supplement to the figures.

In particular, the measures known from the related art for providing selective doping beneath the silver fingers on the front side have not been included in the description, without ruling out that these measures may be used in the cell according to the present invention in order to improve the blue light sensitivity on the front side.

Starting with a roughly purified n-silicon wafer, the following process steps (as an example) result in one preferred specific embodiment of the described cell concept.

1) saw damage etching and (optional) RCA purification of the wafer surfaces (FIG. 1);

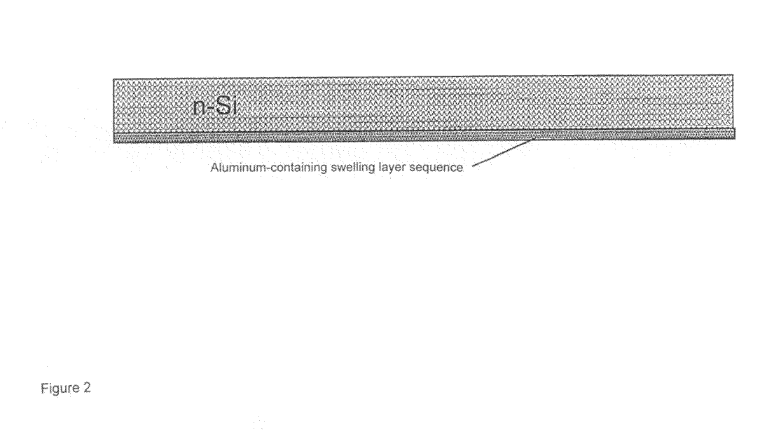

2) coating the back side with an aluminum-containing swelling layer or swelling layer sequence (FIG. 2);

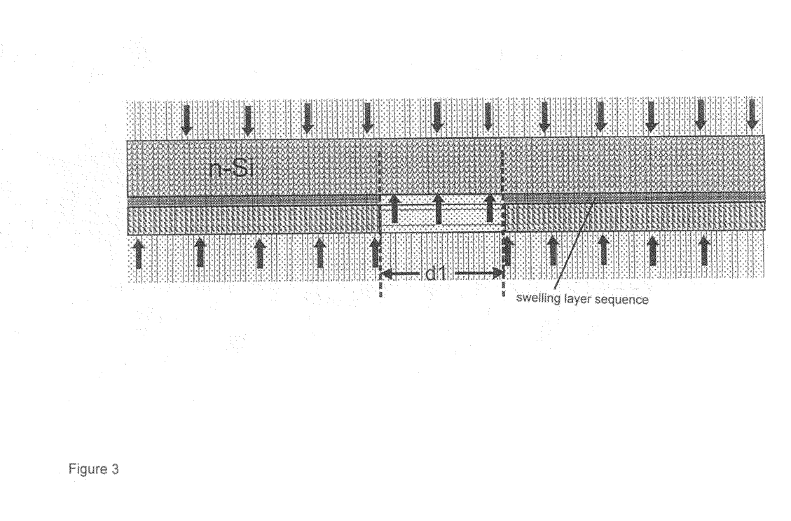

3) removing the swelling layer/swelling layer sequence around the subsequent base busbar regions, preferably by masked etching; the etched-out region (FIG. 3, width d1) is wider than the subsequent base busbar, which is connected to the front-side metal fingers via metal-plated vias;

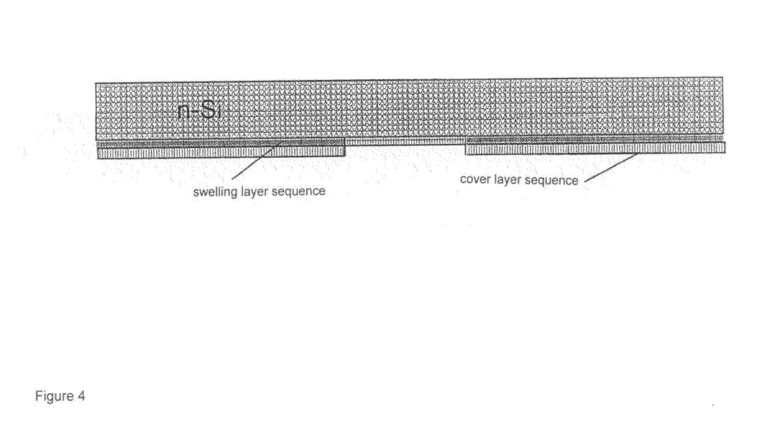

4) depositing an etch-resistant cover layer sequence, which is dielectric with respect to KOH, on the back-side aluminum-containing swelling layer/swelling layer sequence (FIG. 4);

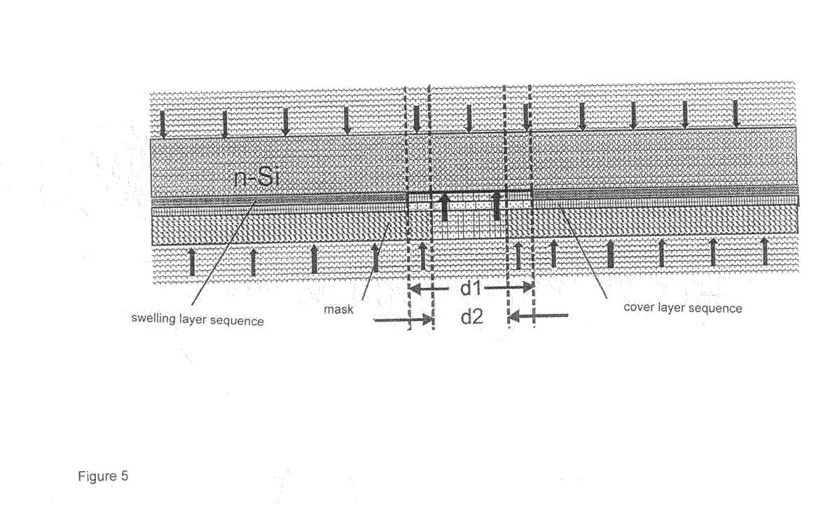

5) opening the dielectric insulation layer in the region of the subsequent base busbars, preferably by masked etching or by etch paste printing, these openings having width d2<d1 defining the structure of the subsequent n⁺ doping and of the base contact surfaces to be printed thereon (FIG. 5);

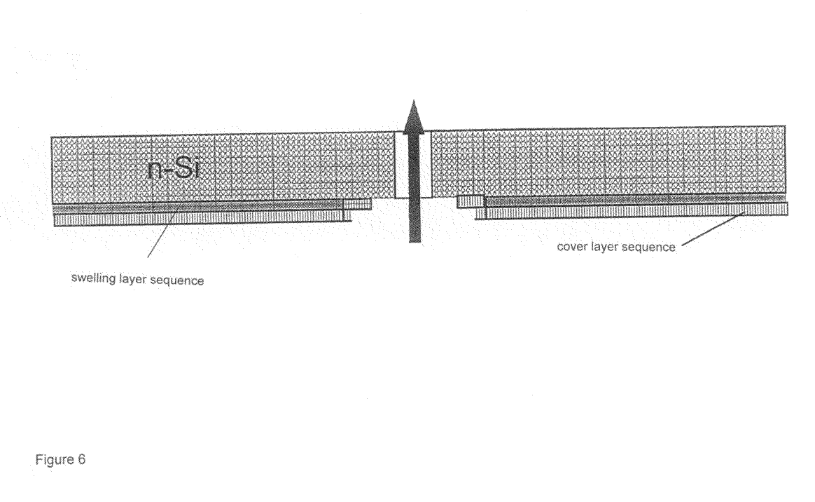

6) producing the vias in the middle of the exposed regions having width d2, by laser bombardment (FIG. 6);

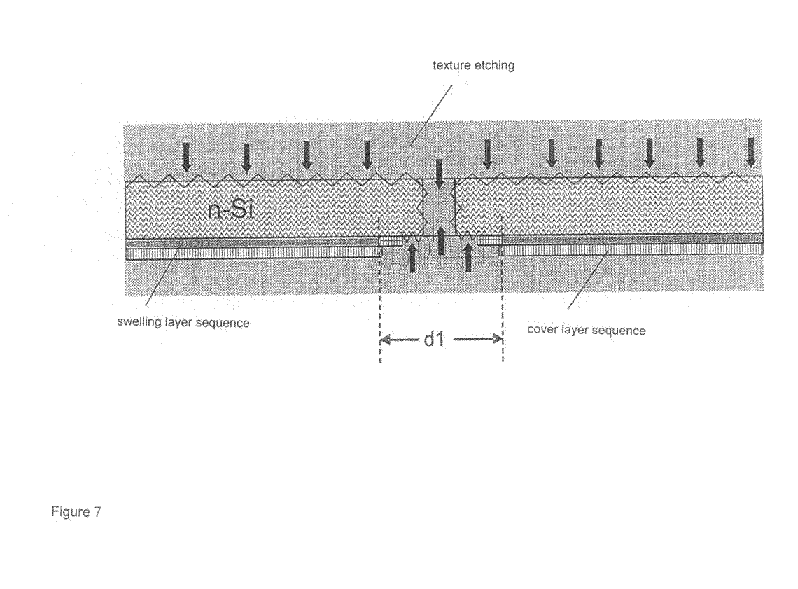

7) texture etching the front side, the hole inner walls, and the base busbar regions of the back side exposed in step 5, using alkaline etching solution and etching away the topmost KOH-resistant layer of the cover layer sequence (FIG. 7);

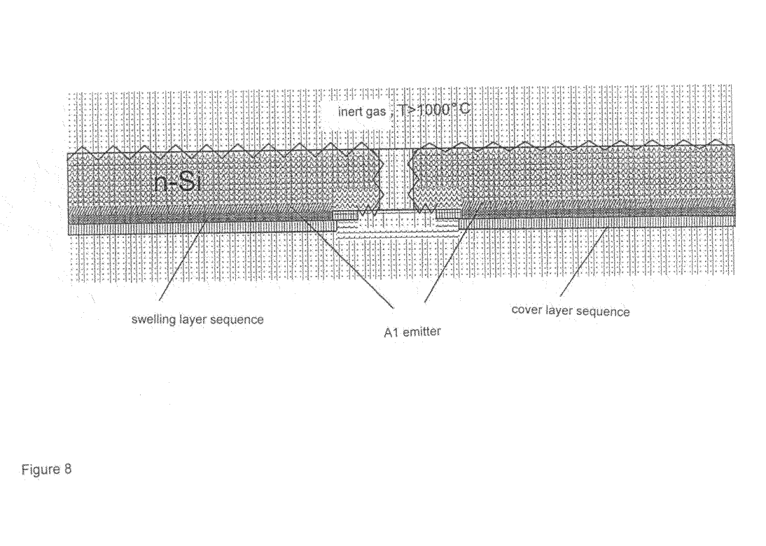

8) high-temperature diffusion of the Al emitter beneath the dielectric cover layer, preferably at T>1000° C. in an inert gas atmosphere (FIG. 8);

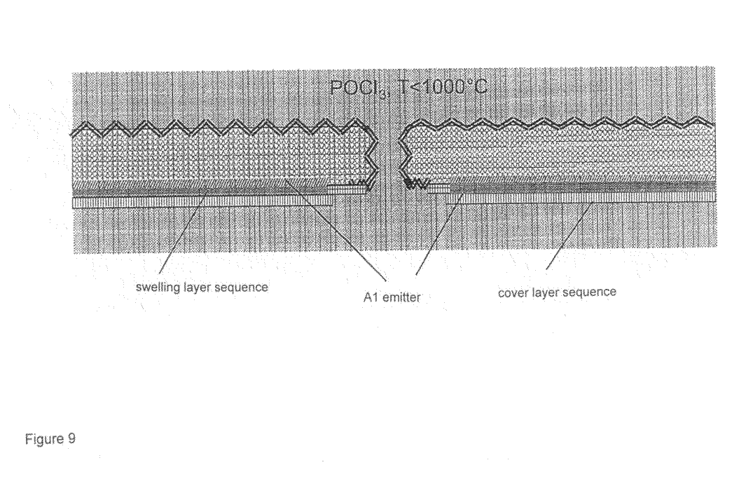

9) phosphorus diffusion at T<1000° C. for providing the n⁺ doping on the front side, the hole inner walls, and the base busbar regions of the back side exposed in step 5 (FIG. 9);

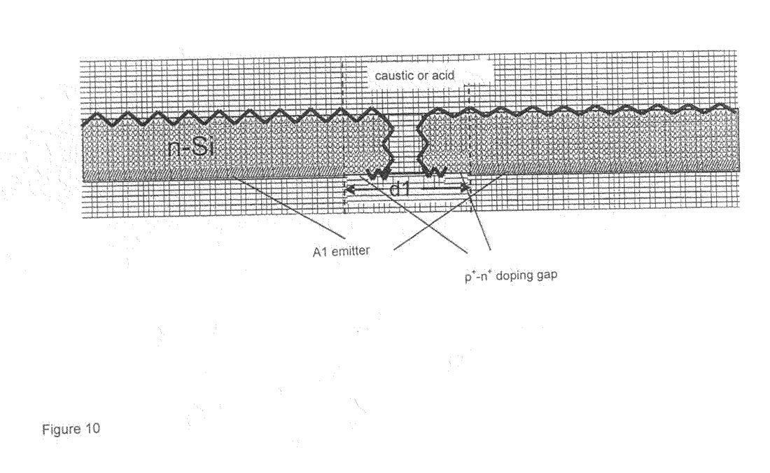

10) back-etching the phosphorus silicate glass (PSG) layer, the back-side cover layer, and the remainders of the swelling layer or remainders of the swelling layer sequence for exposing the back-side emitter and the FSF, on the front side and in places on the back side, in suitable wet chemical baths or in suitable plasma (FIG. 10); due to the fact that the regions etched free in the emitter are wider than the FSF regions, there is a lateral distance between the emitter doping regions and the FSF doping regions (n⁺-p⁺ gaps in FIG. 10) which makes laser insulation unnecessary;

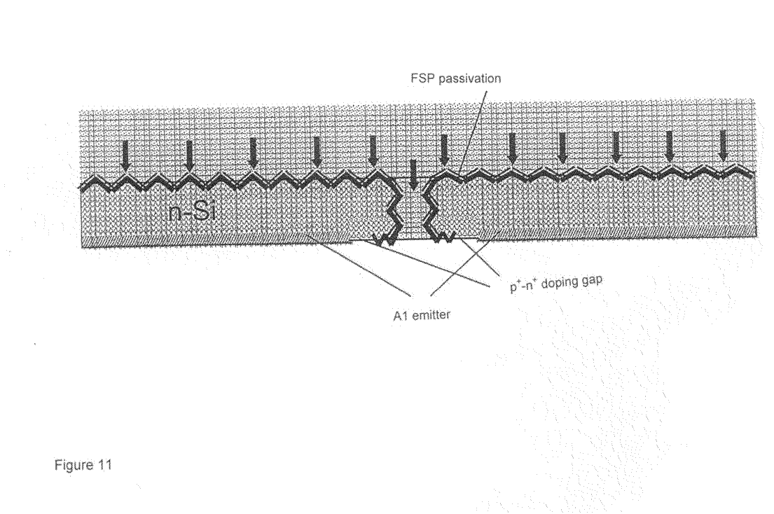

11) depositing the front-side passivation/antireflection layer, preferably by PECVD of silicon nitride, either directly on the semiconductor surface or on a thin oxide which has been previously deposited by oxidation or coating; however, any other double layer composed of a suitable passivation layer, for example amorphous silicon (a-Si:H) or silicon carbide (SiCx), and a suitable antireflection layer, is also possible (FIG. 11);

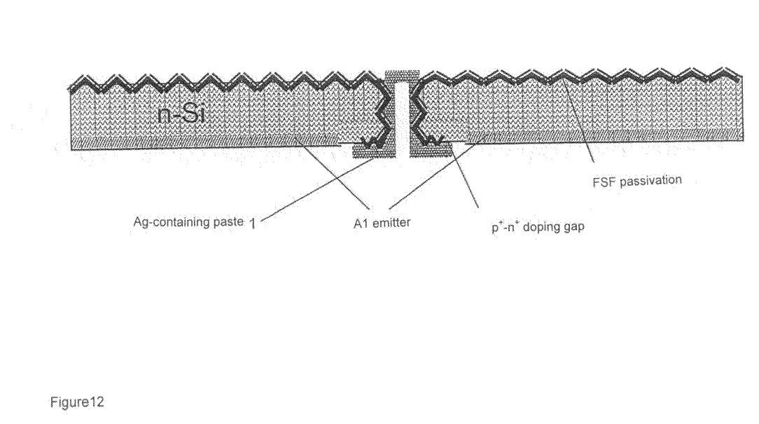

12) printing the back-side base contact surfaces with a suitable first silver-containing paste, with subsequent drawing into the laser-bored holes (vias) and drying of the paste (FIG. 12);

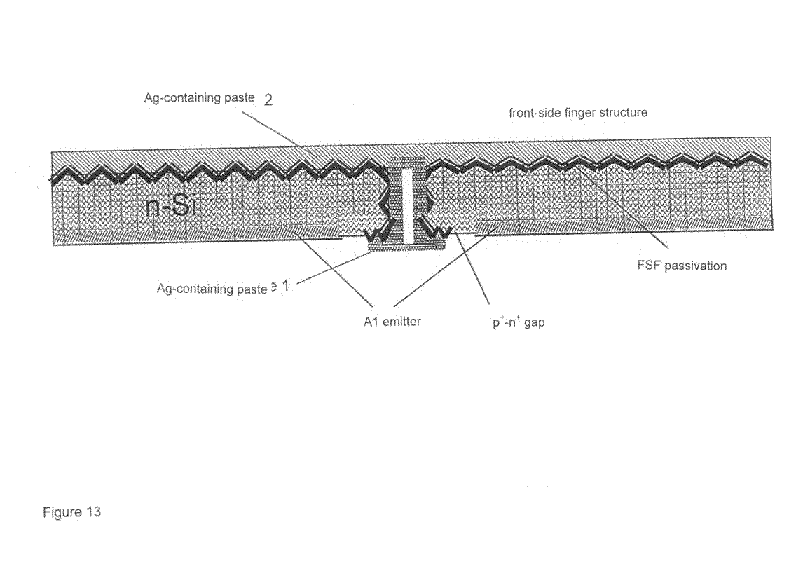

13) printing and drying of the front-side finger structure, using a second silver-containing paste which contacts the first silver-containing paste in the holes in the region of the vias; mutual sintering of the two pastes with firing through the front-side antireflection-passivation layer (sequence) (FIG. 13);

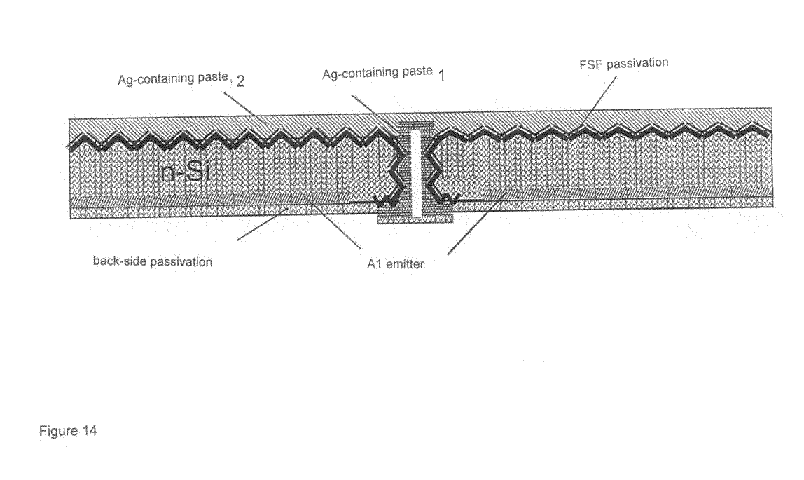

14) optional: full-surface deposition of a back-side passivation layer, for example amorphous silicon (a-Si:H) or aluminum oxide or aluminum fluoride, whose passivation action is specifically tailored to the p⁺ emitter (FIG. 14);

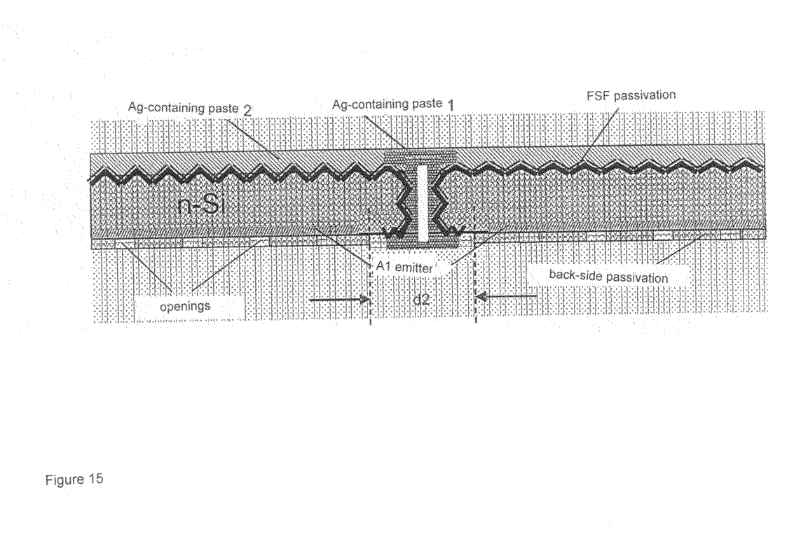

15) optional: structuring the optional back-side passivation layer by masked etching or by etch paste printing; providing local openings for the contact formation on the emitter and exposing the base contact surfaces around the vias, which have already been printed in step 12 using the first Ag-containing paste (FIG. 15);

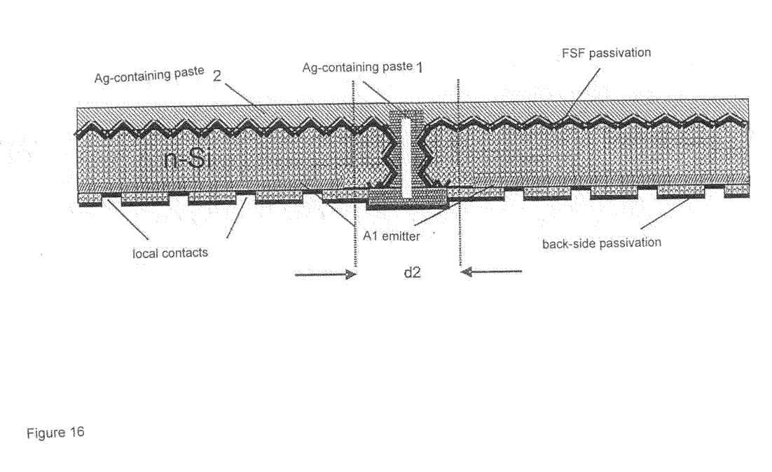

16) full-surface metal plating of the back side directly on the semiconductor or on the optional emitter passivation, and in the windows opened therein in step 15, preferably by vapor deposition or sputtering of aluminum-containing material (FIG. 16);

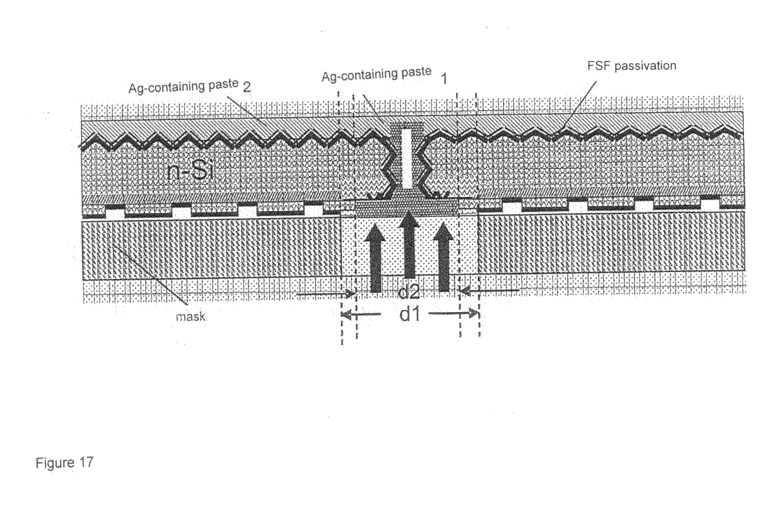

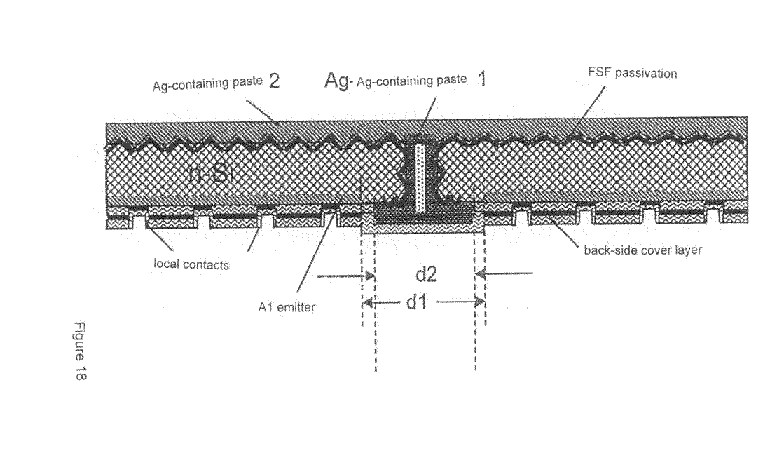

17) structuring the back-side metal plating by masked etching in the chlorine-containing plasma or by etch paste printing; base contacts in particular are exposed (FIG. 17);

18) optional: covering the structured back-side metal plating with a dielectric protective layer (FIG. 18);

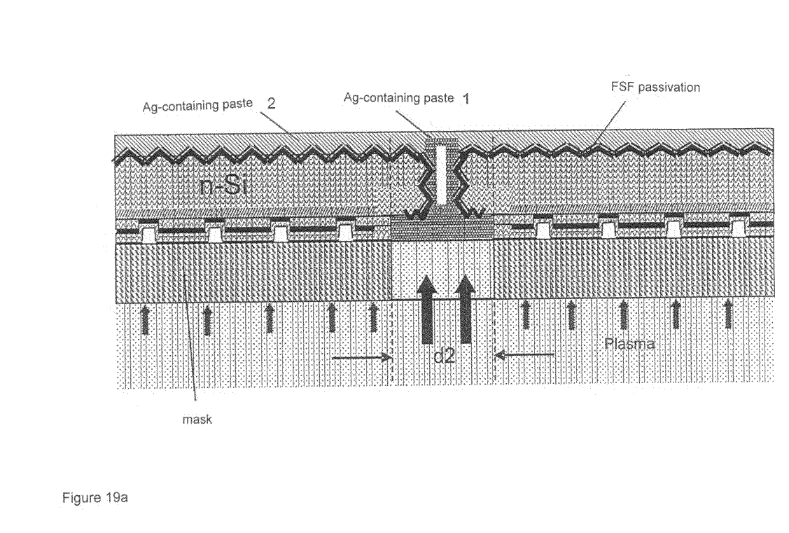

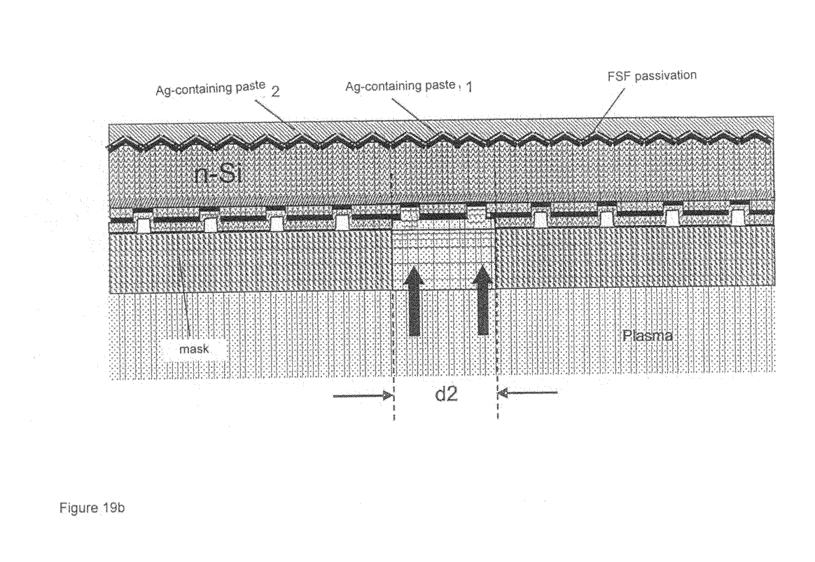

19) optional: local opening of the optional back-side cover layer from step 18, i.e., in particular in the region of the base busbar contact surfaces (FIG. 19a) and laterally in the regions of the subsequent emitter solder contacts (FIG. 19b);

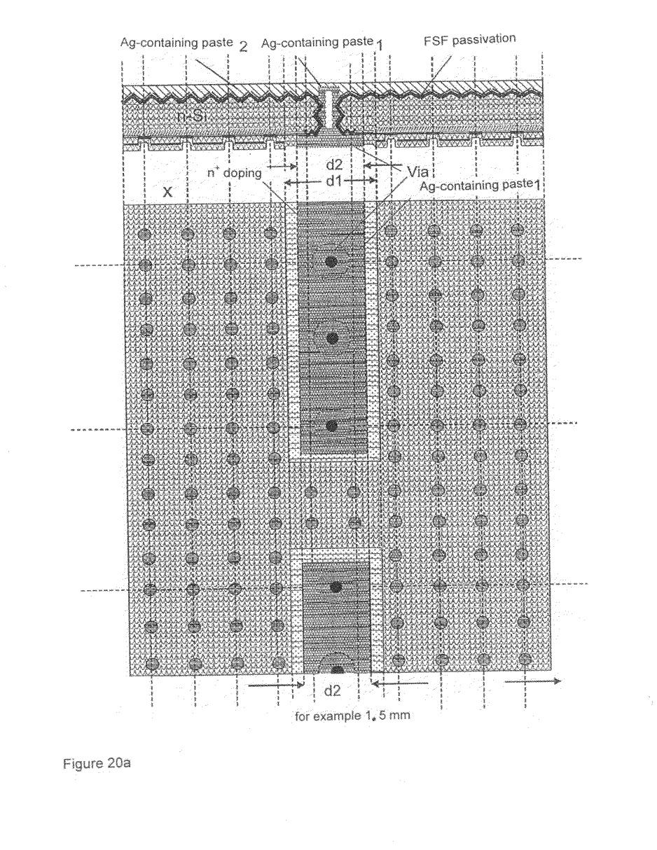

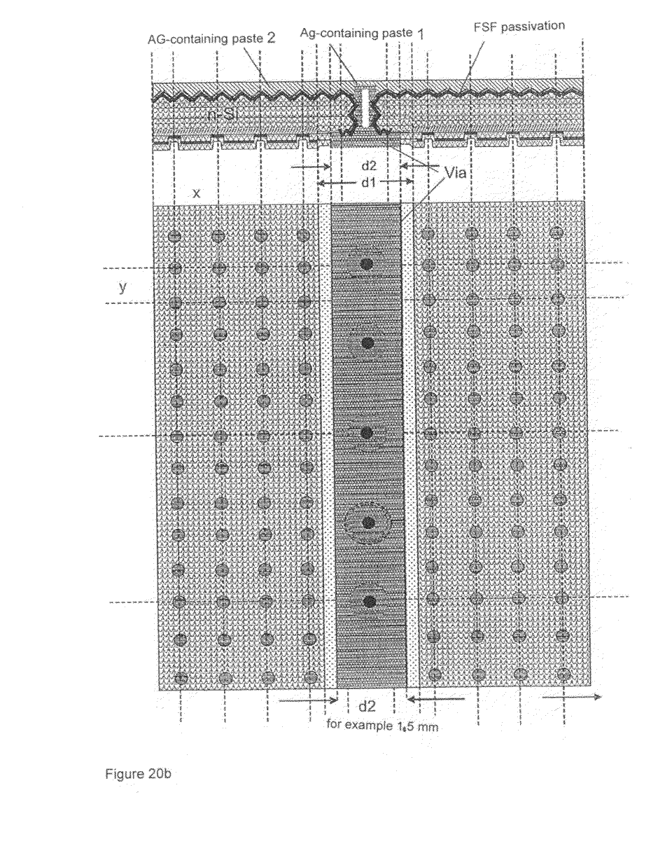

20) The lateral shapes of the openings in the back-side metal plating from step 18 and of the openings in the optional protective layer from step 19 may be different: either
(a) mutually separated strip segments which connect two or more vias with one another (top view in FIG. 20a), emitter regions having local contacts still being situated between these strip segments, or
(b) continuous strips which interconnect all vias in a busbar (top view in FIG. 20b);

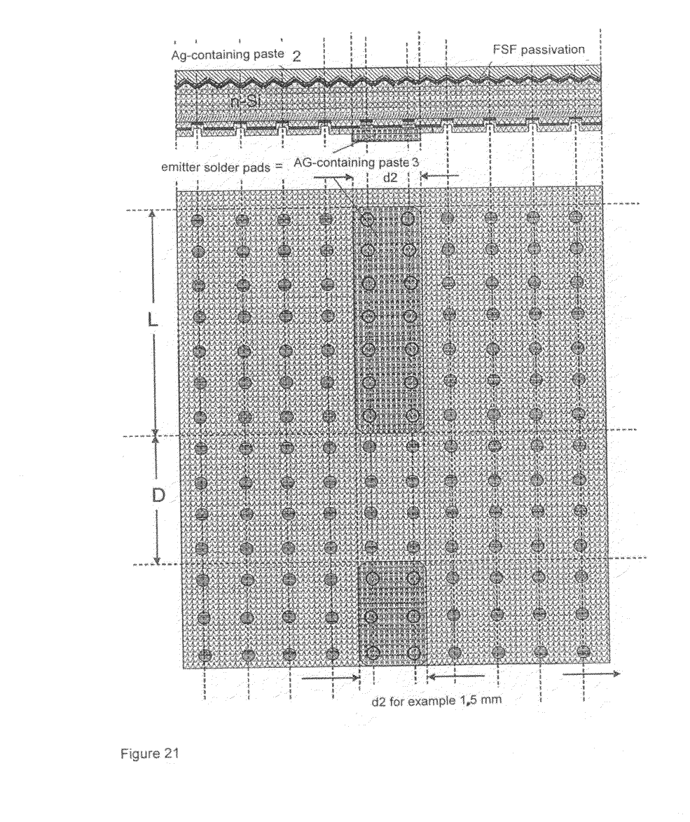

21) printing and drying a third silver-containing (low-temperature) paste in regions of the emitter contact surfaces in the opened regions from step 19 (FIG. 21). The distance between adjacent emitter contact solder dots having length L may be selected as desired, i.e., may also be zero.

The execution of the present invention is not limited to this example, and is also possible in numerous modifications which are within the scope of procedures carried out by those skilled in the art.

1-17. (canceled)

18. A solar cell, comprising:
an n-doped silicon substrate having a first main surface as the incident light side and a second main surface as the back side;
a large-surface n⁺-doped base region provided in the first main surface;
a large-surface p⁺-doped emitter region provided in the second main surface;
a finger-like base contact structure applied to the first main surface;
an emitter contact structure applied to the second main surface;
base contact paths applied to the second main surface and having solderable contact surfaces; and
multiple through-connections which connect the finger-like contact structure of the first main surface to the contact paths on the second main surface, thereby connecting the emitter region and the base regions via solder contact surfaces on the second main surface;
wherein the second main surface is free of p⁺ emitter doping at least in regions of the base contact paths, and wherein the first main surface and predetermined regions of the second main surface have an n⁺n transition at least around the through-connections, thereby providing a front surface field.

19. The solar cell as recited in claim 18, wherein regions on the second main surface between the n⁺-doped base regions and the p⁺-doped emitter region represent a doping gap having only the base doping of a starting material, such that no subsequent insulation for separating the n⁺-doped base regions and the p⁺-doped emitter region is necessary.

20. The solar cell as recited in claim 18, wherein the n⁺ doping of the first main surface is provided using phosphorus, and the p⁺ doping of the second main surface is provided using aluminum.

21. The solar cell as recited in claim 20, wherein the n⁺ doping in the first main surface is higher beneath fingers of the finger-like contact structure than between the fingers.

22. The solar cell as recited in claim 20, wherein an essentially full-surface metal layer made of thin-film aluminum is provided on the second main surface for one of local or large-surface contacting of the emitter, the full-surface metal layer having recesses in regions provided for the base contacting.

23. The solar cell as recited in claim 22, wherein an essentially full-surface dielectric cover layer is provided between the second main surface and the essentially full-surface metal layer, the full-surface dielectric cover layer being provided with openings at multiple contact points and in all regions having an n⁺n transition, and the openings around the multiple through-connections being smaller than the corresponding n⁺n regions present around the through-connections.

24. The solar cell as recited in claim 22, wherein the metal-plated n⁺n regions present on the second main surface are provided as one of (i) at least two contiguous busbar strips, in each case over the entire wafer length, or (ii) segments having a distance from one another in the range of at least one finger interval of the contact structure.

25. The solar cell as recited in claim 23, wherein recesses in the dielectric layer are provided on the second main surface in the n⁺n transition regions beneath the base contact surfaces, essentially congruent with the shape of the recesses in the emitter region and in the surface metal layer, the recesses in the dielectric layer being smaller than the recesses in the emitter region and in the surface metal layer.

26. The solar cell as recited in claim 23, wherein the finger-like contact structure on the first main surface is formed from (i) one of a silver-containing screen printing paste or aerosol printing ink, and (ii) an antireflection coating.

27. A method for manufacturing a solar cell including an n-doped silicon substrate having a first main surface as the incident light side and a second main surface as the back side; a large-surface n⁺-doped base region provided in the first main surface; a large-surface p⁺-doped emitter region provided in the second main surface; a finger-like base contact structure applied to the first main surface; an emitter contact structure applied to the second main surface; base contact paths applied to the second main surface and having solderable contact surfaces; and multiple through-connections which connect the finger-like contact structure of the first main surface to the contact paths on the second main surface, thereby connecting the emitter region and the base regions via solder contact surfaces on the second main surface; wherein the second main surface is free of p⁺ emitter doping at least in regions of the base contact paths, and wherein the first main surface and predetermined regions of the second main surface have an n⁺n transition at least around the through-connections, thereby providing a front surface field, the method comprising:
providing the n⁺ doping in the first main surface and in the predetermined regions of the second main surface using the gas phase, wherein a higher doping is provided beneath the fingers of the contact structure on the first main surface than between the fingers, thereby providing a selective front surface field.

28. The method as recited in claim 27, wherein the p⁺ doping of the emitter region on the second main surface is provided by diffusion of aluminum from an Al-containing swelling layer applied to the complete second main surface, and wherein, before diffusion of the Al into the second main surface, predetermined regions of the Al-containing swelling layer are removed to provide regions in which n⁺ transition or no higher-level doping is to be present.

29. The method as recited in claim 28, wherein the Al-containing swelling layer and a dielectric cover layer are applied to the second main surface by one of a vacuum or gas phase deposition process.

30. The method as recited in claim 29, wherein the Al-containing swelling layer and the dielectric cover layer on the second main surface are structured by local selective etching using one of etching paste or by masked plasma-supported reactive ion etching.

31. The method as recited in claim 30, wherein:
the n⁺ doping of the first main surface is provided using phosphorus;
after the diffusion of the phosphorus into the first main surface, the walls of the through-connections, and the predetermined regions of the second main surface, and after the diffusion of the aluminum into the second main surface, the phosphorus silicate glass layer formed during the phosphorus doping in the regions of the front surface field, the Al-containing swelling layer, and the dielectric cover layer are completely etched away;
the second main surface is subsequently completely covered using a deposition process with a metal layer for contacting the emitter region; and
the metal layer is subsequently locally removed, using an etching process with the aid of masking, in predetermined regions corresponding to the regions for n⁺n transitions.

32. The method as recited in claim 31, wherein before the step of depositing the metal layer on the second main surface, a full-surface dielectric passivation layer is applied, and the full-surface dielectric passivation layer is locally opened at multiple contact points and in the regions provided for n⁺n transitions.

33. The method as recited in claim 31, wherein the second main surface is completely covered with a dielectric protective layer which is subsequently locally opened only in the regions on the p⁺ and n⁺ areas which are provided for solder contact surfaces.

34. The method as recited in claim 31, wherein the p⁺-regions on the second main surface which are provided as emitter contact surfaces are imprinted with a silver-containing screen printing paste which is sintered at temperatures below 560° C.
